(19) United States
(12) Patent Application Publication
(10) Pub. No.: US 2014/0118986 A1
(43) Pub. Date: May 1, 2014

(54) ONBOARD ELECTRONIC CONTROL UNIT

(71) Applicant: SUMITOMO WIRING SYSTEMS, LTD., Yokkaichi (JP)

(72) Inventors: Kenta SUZUKI, Yokkaichi-city (JP); Takaki KISHIDA, Yokkaichi-city (JP); Takehiro KANOU, Yokkaichi-city (JP)

(73) Assignee: SUMITOMO WIRING SYSTEMS, LTD., Yokkaichi (JP)

(21) Appl. No.: 13/961,314

(22) Filed: Aug. 7, 2013

(30) Foreign Application Priority Data
Oct. 31, 2012 (JP) 2012-241057

(51) Int. Cl. H05K 5/00

(52) U.S. Cl. CPC H05K 5/0056
USPC 361/821

(57) ABSTRACT

Some embodiments protect aluminum electrolytic capacitors without increasing the thickness or height dimension of a unit case of an onboard electronic control unit, which is provided with the unit case and a circuit board on which the aluminum electrolytic capacitors are mounted. The circuit board includes a first surface and a second surface, and the unit case houses the circuit board. The unit case includes a first main wall facing the first surface, a second main wall facing the second surface, and perimeter walls. The capacitors are mounted on the second surface so as to extend along a specific periphery of the circuit board and be mutually connected in parallel. The unit case has a height dimension capable of housing the aluminum electrolytic capacitors without the aluminum electrolytic capacitors contacting the inside surface of the second main wall.

### BACKGROUND

Some embodiments relate to an onboard electronic control unit for providing electronic control, such as in the content of a vehicle, e.g., automobile. Some of these embodiments include a circuit board and are mounted in the case of an electric connection box provided in the vehicle.

The related art includes onboard electronic control units with built-in electronic control circuits, which have become more common along with the increased use of electronics in vehicles. For example, Japanese Patent Application Publication No. 2010-226855 (JP 855) discloses mounting an electronic control unit in the case of an onboard electric connection box provided in an automobile. This electronic control unit has a built-in circuit board for electronic control, and is electrically connected to circuit constituents (such as a bus bar substrate housed in the case) by virtue of it being mounted in the case of the electric connection box.

The electronic control unit with built-in circuit board are housed in the unit case. This unit case is generally divided into a case body and a cover, and with the circuit board inserted into the case body, the cover is mounted on the case body so as to cover the circuit board.

A variety of electronic components are mounted on this circuit board, and the tallest of these components is typically an aluminum electrolytic capacitor, as disclosed in Japanese patent Application Publication No. 2009-212236 (JP 236). In the electronic control units that contain this aluminum electrolytic capacitor, a height dimension of the unit case is set so that the capacitor does not come into contact with the inner surface of the cover or the case body of this unit case.

### SUMMARY

It is very likely that a large external force will be applied to the unit case of the electronic control unit in the height direction. For example, as disclosed in (JP 855), the unit case of the electronic control unit (which is mounted in the case of the electric connection box) receives a relatively large external force in the height direction by a user grasping the unit case in the height direction. For example, the user may grasp the exterior of the unit case with the user's fingers. This outside force elastically bends and displaces the unit case inward. Accordingly, when the electronic control unit includes a tall aluminum electrolytic capacitor (such as that described above), a large gap needs to be set between the aluminum electrolytic capacitor and the inside surface of the unit case in order to reliably avoid contact between these two elements when the aforementioned bending displacement occurs. This configuration (i.e., the large gap) becomes a major impediment to reducing the height dimension of the unit case. In addition, increasing the thickness of the unit case to increase the rigidity thereof and thereby control this bending displacement leads to increases in costs of materials and total weight, thereby inhibiting reductions in weight and cost.

It may therefore be advantageous to provide an electronic control unit that includes a circuit board, on which an aluminum electrolytic capacitor is mounted, and a unit case for housing the electronic control unit, that is configured to reliably avoid contact between the aluminum electrolytic capacitor and the inside surface of the unit case when the unit case is pressed from its exterior. It may be particularly advantageous to provide this feature without making the height dimension of the unit case or the thickness particularly large.

Some embodiments therefore provide an onboard electronic control unit that includes a circuit board that defines a first surface and an opposite second surface, and on which an electronic control circuit is formed. A unit case houses the circuit board. The unit case includes a first main wall facing the first surface when the circuit board is housed in the unit case, a second main wall facing the second surface, and perimeter walls encompassing the circuit board from the exterior and linking the first main wall and the second main wall. A plurality of aluminum electrolytic capacitors are mounted on the second surface of the circuit board so as to extend along a specific periphery of the circuit board and be mutually connected in parallel. The unit case has a height dimension capable of housing the aluminum electrolytic capacitors without the capacitors contacting the inside surface of the second main wall.

A plurality of aluminum electrolytic capacitors mutually connected in parallel, are mounted on the circuit board. This configuration is contrasted with the related art ease where a single aluminum electrolytic capacitor, which has the same capacitance as the combined capacitances as the plurality of capacitors, is mounted on the circuit board, and thereby reduces the height dimension of each aluminum electrolytic capacitor. Moreover, the plurality or aluminum electrolytic capacitors are arranged along a specific periphery of the circuit board, so that the part of the second main wall of the unit case that is disclosed in proximity to the side wall, (i.e., the inside surface of the part with a small bending displacement when this second main wall is pressed), faces the aluminum electrolytic capacitors. This configuration makes it possible to avoid contact between the inside surface of the second main wall and the aluminum electrolytic capacitors, without particularly enlarging the thickness of this second main wall, or particularly enlarging the gap between the inside surface of the second main wall and the aluminum electrolytic capacitors.

The unit case may include: 1) a first case member having a first side wall defining the first main wall, and a portion of the perimeter wall and into which the circuit board is insertable in an attitude with the first main wall and the first surface of the circuit board facing each other inside of the first side wall, and 2) a second case member having a second side wall defining the perimeter wall along with the second main wall and the first side wall, and being joined to the first case member so as to cover the circuit board in an attitude in which the second main wall faces the second surface of the circuit board.

The first case member may have a first reinforcement protruding to the inside from the first side wall, and linking to the first main wall. The second case member may have a second reinforcement protruding to the inside from the second side wall, and linking to the second main wall. The positions of the first and second reinforcements are set so that, with the first case member and the second case member joined, the first and second reinforcements interpose in the height direction thereof both sides of a portion of at least the specific periphery of the circuit board. Also, a reinforcement structure is built in which the first main wall, the first reinforcement, the periphery, the second reinforcement and the second main wall are connected (in this order) in the direction of height for the specific periphery. This configuration enables the bending displacement of the second main wall near the specific periphery to be effectively controlled. This configuration also enables the gap between aluminum electrolytic capacitors, arranged along the specific periphery and the inside surface of the second main wall, to be set to be smaller than in the related art. Moreover, because in some embodiments, the two reinforcements interpose at least one portion of the specific periphery of the circuit board, the extent to which these reinforcements limit the mountable area for components on the circuit board is extremely low.

More specifically, when the circuit board has a shape that defines a plurality of corners (for example, a quadrilateral having four corners), the first and second reinforcements may be provided so as to interpose these corners. This structure makes it possible to effectively control the bending displacement of the effective reinforcement, i.e., the second main wall, while suppressing, to the extent possible, limitations on the mountable region for various parts in a circuit board due to placement of the reinforcements.

As described above, some embodiments provide an electronic control unit that includes a circuit board on which an aluminum electrolytic capacitor is mounted, and a unit case for housing the electronic control unit. This configuration makes it possible to reliably avoid contact between the aluminum electrolytic capacitor and the inside surface of the unit case, when the unit case is pressed from the exterior, without making the height dimension of the unit case or the thickness particularly large.

### BRIEF DESCRIPTION OF THE DRAWINGS

FIG. 1 is an oblique view showing a case of an electric connection box and an electronic control unit mounted thereon, according to an exemplary embodiment of the present invention.

FIG. 2 is a disassembled oblique view of the electronic control unit.

FIG. 3 is a plan view of the electronic control unit.

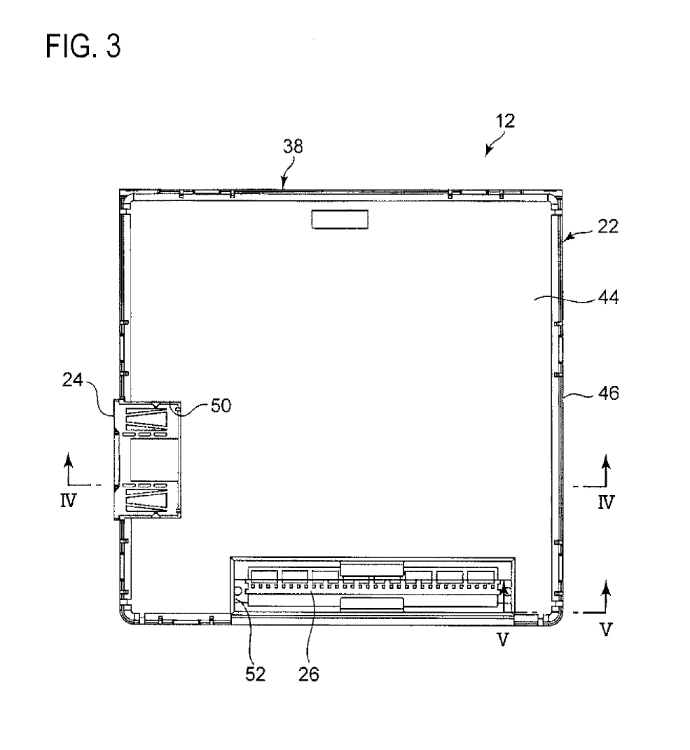

FIG. 4 is a cross-sectional view taken along line IV-IV in FIG. 3.

FIG. 5 is a cross-sectional view taken along line V-V in FIG. 3.

FIG. 6 is a plan view showing the state of the electronic control unit with the cover removed.

FIG. 7 is a plan view of a case body of the electronic control unit.

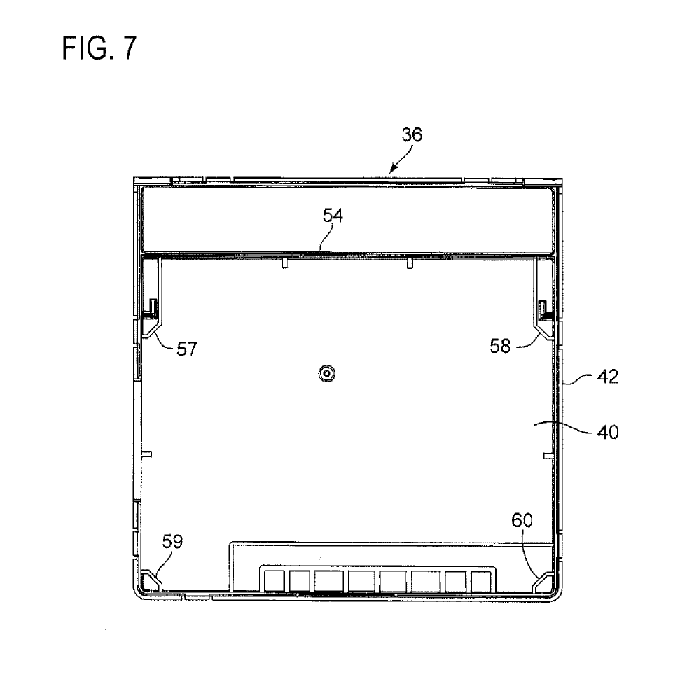

FIG. 8 is a bottom view of the cover.

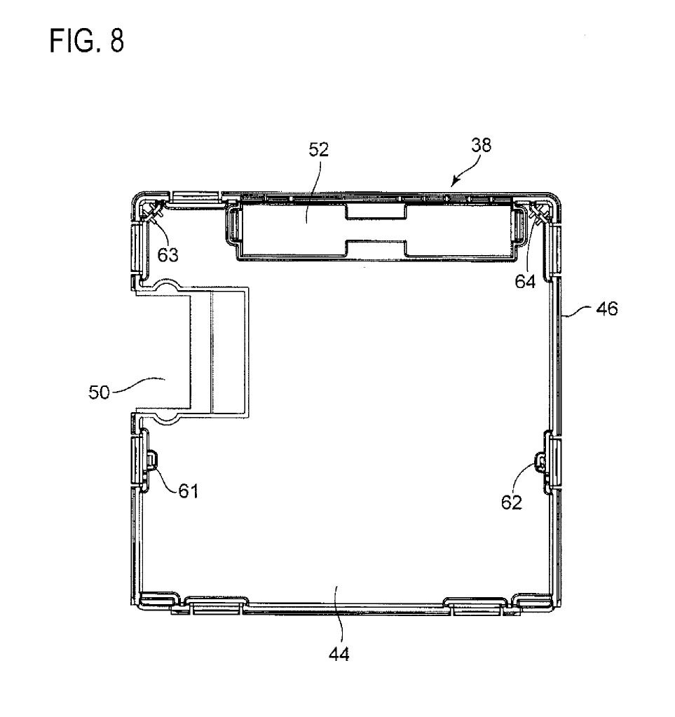

FIG. 9 is cross-sectional view corresponding to FIG. 4 showing a comparison example for the electronic control unit.

### DETAILED DESCRIPTION OF THE EMBODIMENTS

An exemplary embodiment of the present invention is described below with reference to the drawings.

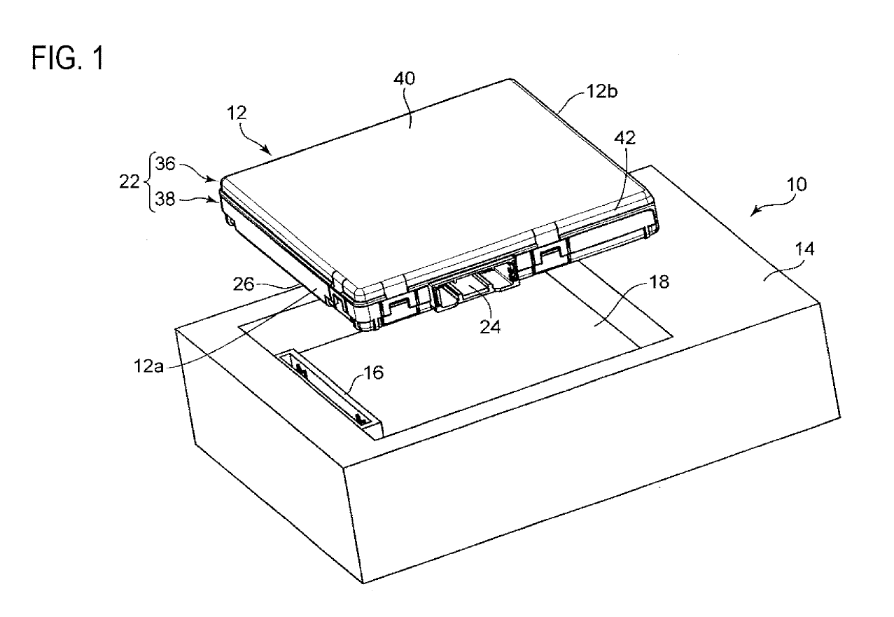

FIG. 1 shows an electric connection box 10 that can be installed in a vehicle, such as an automobile, and an electronic control unit 12 mounted therein. The electric connection box 10 includes a case 14 and a unit connection connector 16. The case 14 houses a bus bar substrate (not shown) forming an electric circuit, and also defines a sunken area 18 for receiving the electronic control unit 12, and thus the sunken area 18 opens in a specified direction (upward in FIG. 1). The unit connection connector 16 connects the bus bar substrate and the electronic control unit 12, and in this embodiment, is positioned inside the sunken area 18 and protrudes upward from the bottom surface of the sunken area 18 so as to be connectable with the electronic control unit 12 mounted within the sunken area 18.

The electronic control unit 12 has an exterior shape capable of being housed within the sunken area 18, and in this housed state is mounted in the case 14 and is connected to the unit connection connector 16.

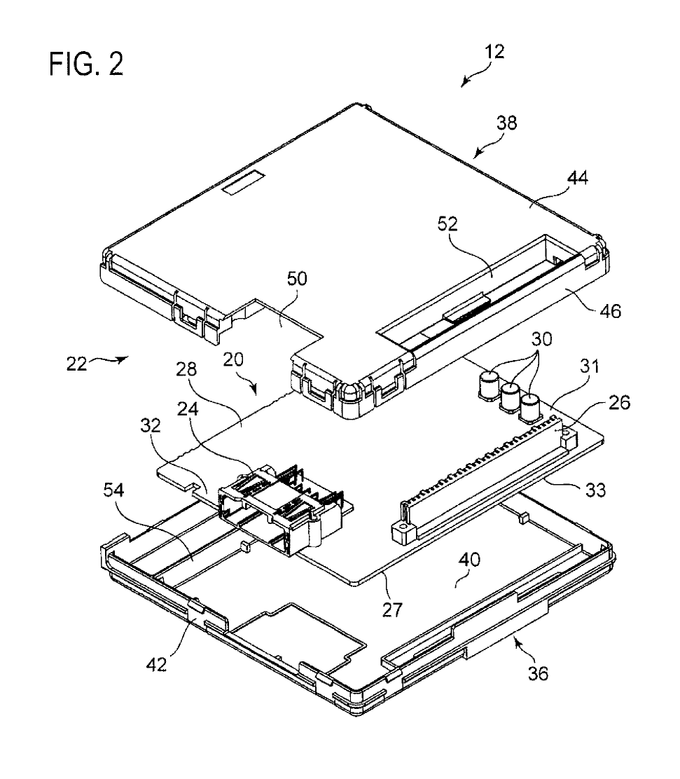

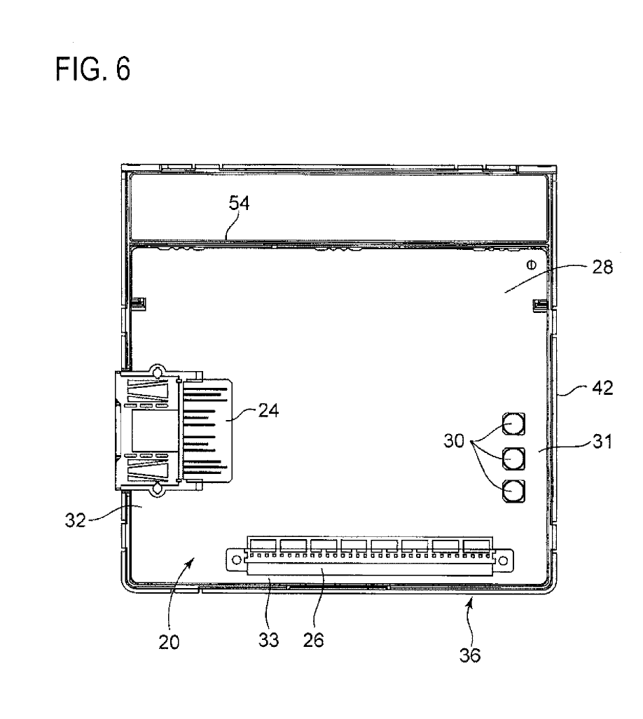

The electronic control unit 12 includes a circuit board 20 (as shown in FIGS. 2 and 6), a unit case 22 for housing the circuit board, an external connection connector 24 mounted on the circuit board 20, and an electric connection box connection connector 26.

The circuit board 20 includes a printed circuit board, for example, and forms an electronic control circuit to be connected to the electric circuit. This circuit board 20 has a roughly square shape in the example shown in FIG. 2, and includes a first surface 27 (that is the bottom surface in the attitude of FIG. 2, but is the top surface in the attitude of FIG. 1), and a second surface 28 on the opposite side thereof, and various circuit constituent components are mounted primarily on this second surface 28.

The circuit constituent components include a plurality of aluminum electrolytic capacitors 30, which are components having the largest height dimension. The aluminum electrolytic capacitors 30 have mutually identical shapes in this embodiment, and are mounted on the second surface 28 so as to be lined-up along a specific periphery of the four peripheries (four sides) of the circuit board 20, which in this embodiment is along a first periphery 31, positioned between the first edge 12a where the electric connection box connecting connector 26 is disposed, and a second edge 12b (see FIG. 1) on the opposite side therefrom, as is described below, and so as to be mutually connected in parallel.

The external connection connector 24 connects the circuit board 20 and an external wire harness, and in this embodiment is mounted on the second surface 28 on a second periphery 32 on the side opposite the first periphery 31. The electric connection box connecting connector 26 connects an electric circuit formed by the bus bar substrate with an electronic control circuit formed by the circuit board 20 by joining with the unit connection connector 16 when the electronic control unit 20 is mounted in the case 14, and is mounted on the second surface 28 so as to follow a third periphery 33, that is a periphery adjacent to both the first and second peripheries 31 and 32 of the peripheries of the circuit board 20, and that is a periphery corresponding to a revolving end 12b (FIG. 1) of the electronic control unit 12.

The unit case 22 is formed of an insulating material, such as synthetic resin, for example, and in this embodiment includes a case 36 corresponding to a first case member and a cover 38 corresponding to a second case member.

The case body 36 includes a first main wall 40, a first outer perimeter wall 42, and an interior wall 54, which define a single body. The first main wall 40 faces the first surface 27 in the housed state of the circuit board 20, and the first outer perimeter wall 42 protrudes toward the cover 38 side along the entire perimeter from the circumference of the first main wall 40. The interior wall 54 is disposed so as to cover the gap between the shape of the first outer perimeter wall 42, and the outside shape of the circuit board 20 (the dimension along the first and second peripheries 31 and 32 of the circuit board 20 are smaller than the first outer perimeter wall 42), and protrudes toward the cover 38 side from a specific location of the first main wall 40. In other words, in this embodiment, in order to make it possible for multiple types of circuit boards 20 of mutually differing sizes to be housed inside the unit case 22 (whose outer shape is standardized for mounting in the case 14 of the electric connection box 10), the inner wall 54 is positioned in conjunction with the shape of the circuit board 20 housed therein, and the position of the inner wall 54 is set so that the circuit board 20 can be inserted with virtually no gaps inside the area encompassed by the three sides of the first outer perimeter wall 42 and this inner wall 54.

On the other hand, the cover 38 has a second main wall 44 and a second outer perimeter wall 46 formed as a single body. The second main wall 44 faces the second surface 28 of the circuit board 20 in the housed state, and the second outer perimeter wall 46 protrudes toward the case body 36 side across the entire perimeter thereof from the periphery of the second main wall 44. Furthermore, as shown in FIG. 6, the second outer perimeter wall 46 overlaps the outside of the first outer perimeter wall 42, and is bonded therewith so as to cover the circuit board 20 in an attitude with the second main wall 44 facing the second surface 28, with respect to the circuit board 20 inserted inside the case body 36. In accordance with this configuration, the cover 38 completes the housed state of the circuit board 20 mounted in the case body 36. In this embodiment, the sunken area 18 is formed to extend across the entire perimeter of the inside surface of the second outer perimeter wall 46 is formed, and both perimeter walls 42 and 46 mutually bond so that the edges of the first outer perimeter wall 42 interlock with this sunken area 18. In addition, holes 50 and 52 are formed in the cover 38 so that the outside of the external connection connector 24 and the electric connection box connecting connector 26 are exposed to the exterior.

Accordingly, the inner wall 54 and a portion of the first outer perimeter wall 42 and the second outer perimeter wall 46 form a perimeter wall surrounding from the outside the circuit board 20 in the housed state. Specifically, the inner wall 54 in the case body 36 and a portion of the first outer perimeter wall 42 (the portion including four sides along with the inner wall 54) correspond to a first side wall forming a portion of the perimeter wall of the unit case 22, and a portion of the second outer perimeter wall 46 in the cover 38 corresponds to a second side wall forming a portion of the perimeter wall of the unit case 22.

Furthermore, a first reinforcement and a second reinforcement are respectively provided in the case body 36 and the cover 38 to increase the rigidity thereof.

Specifically, in the case body 36, rib-shaped circuit board receivers 57, 58, 59, and 60, which are the first reinforcement, are fainted at positions respectively corresponding to the four corners of the circuit board 20. Of these, the circuit board receivers 57 and 58 protrude to the inside from the two inside surfaces respectively interposing the two corners of the inner wall 54 side, i.e., the inside surface of the inside wall and the inside surface of the first outer perimeter wall 42, and the circuit board receivers 59 and 60 protrude to the inside from the two inside surfaces of the first outer perimeter wall 42 respectively interposing the two corners on the opposite side. Furthermore, these circuit board receivers 57-60 are all formed integrally with the first main wall 40.

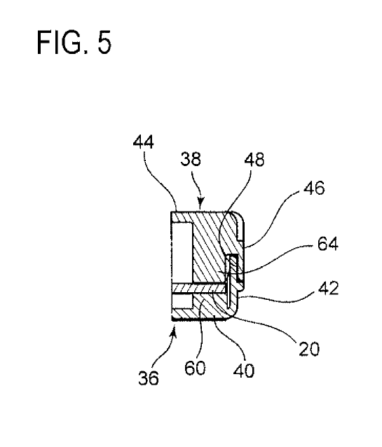

Similarly, in the cover 38, circuit board anchor ribs 61, 62, 63 and 64, which are respectively the second reinforcement, are formed at positions corresponding to the circuit board receivers 57, 58, 59 and 60. These circuit board anchor ribs 61-64 protrude to the inside from the two inside surfaces of the second outer perimeter wall 46, respectively interposing the four corners corresponding to the circuit board receivers 57-60, and are formed integrally with the second main wall 44. Furthermore, as shown in FIG. 5, the height dimensions of each of the circuit board receivers 57-60 and each of the circuit board anchor ribs 61-64 (the dimension in a direction parallel to the direction of height of the unit case 22) are set to that in the circuit board 20 housed state the circuit board receivers 57-60 (FIG. 5 shows the circuit board receiver 60 as a representative), and the circuit board anchor ribs 61-64 (FIG. 5 shows the circuit board anchor rib 64 as a representative) respectively corresponding thereto interpose the corners of the circuit board 20 from both sides in the height direction.

This electronic control unit 12 makes it possible to reduce the height dimension of the unit case 22, while reliably protecting the aluminum electrolytic capacitors 30 without making the thickness particularly large. The configuration that provides these features is discussed below.

When the electronic control unit 12 is mounted in a case 14 of the electric connection box 10 (shown in FIG. 1), it is necessary for a worker to firmly grasp the unit case 22 thereof with fingers or the like, and in addition, to strongly press the unit case 22 against the case 14. Consequently, there is a high possibility that a strong pressing force in the height direction thereof will act on, i.e., a relatively large external force will be applied to, this unit case 22, and this external force will act as a force that bends and displaces the main walls 40 and 44 in the height direction. Accordingly, in order for this external force not to be conveyed to the aluminum electrolytic capacitors 30, a gap between the second main wall 44 and the aluminum electrolytic capacitors 30 must be provided in anticipation of the bending displacement of the second main wall 44, and the height dimension sought in the unit case 22 becomes larger by the amount of that gap.

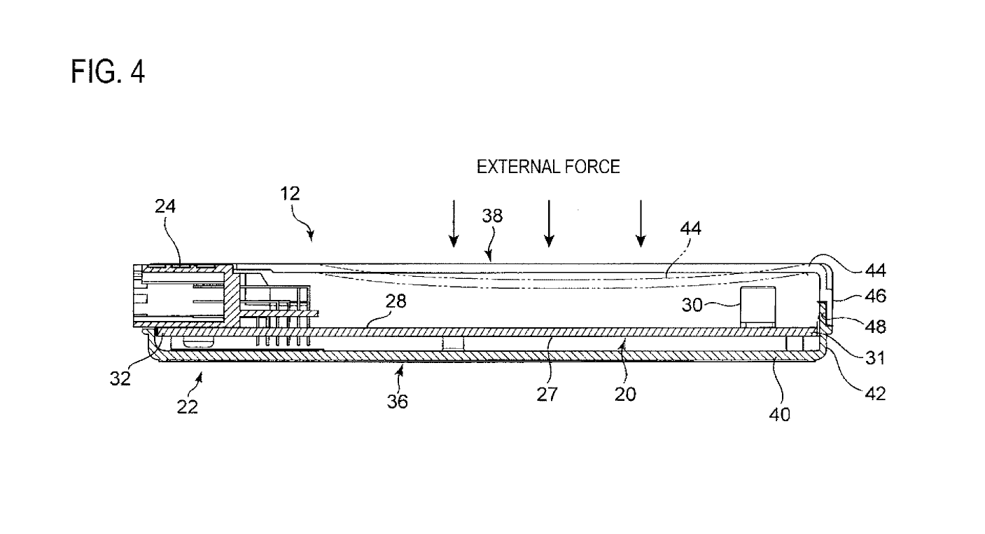

The electronic control unit 12 is provided with a plurality of aluminum electrolytic capacitors 30, and these aluminum electrolytic capacitors 30 are mounted on the circuit board 20 mutually connected in parallel, so that compared to providing a single aluminum electrolytic capacitor having the same capacitance as the total capacitance of these aluminum electrolytic capacitors 30, it is possible to reduce the height dimension of the aluminum electrolytic capacitors 30. In addition, these aluminum electrolytic capacitors 30 are arranged lined up along a specific periphery (the first periphery 31) of the circuit board 20, and through this configuration it is possible to cause a part where there is particularly small bending displacement of the second main wall 44, i.e., a part near the second outer perimeter wall 42, to face the aluminum electrolytic capacitors 30. Specifically, when the external force shown in FIG. 4 is applied to the second main wall 44, the central position of the second main wall 44 bends and displaces greatly in the inward direction as indicated by the double-dashed line in the drawing, but the plurality of aluminum electrolytic capacitors 30 on the circuit board 20 are all concentrated and positioned along the first periphery 31, and in that position the bending displacement of the second main wall 44 is small, so the gap that must be secured between the second main wall 44 and the aluminum electrolytic capacitors 30 need only be small.

In other words, in the electronic control unit 12, dispersing and placing the aluminum electrolytic capacitors 30 in a plurality of positions along the first periphery 31 makes it possible to simultaneously realize reduction of the height dimension of the aluminum electrolytic capacitors 30 and suppression of the bending displacement of the part of the cover 38 covering the aluminum electrolytic capacitors 30, and through this, it becomes possible to reduce the height dimension of the unit case 22 without increasing the thickness of the cover 38.

In the electronic control unit 12 according to this embodiment, circuit board receivers 57-60 and circuit board anchor ribs 61-64 are respectively provided in the case body 36 and the cover 38 for the four corners of the circuit board 20 including the two corners that are on part of the first periphery 31, and these elements have dimensions for interposing each corner of the circuit board 20 from both sides in the height direction, and consequently, in each corner, a reinforced structure is created in which the first main wall 40, a circuit board receiver 57, 58, 59 or 60, a corner of the circuit board 20, a circuit board anchor rib 61, 62, 63 or 64, and the second main wall 44 are connected in this order in the height direction. This configuration makes it possible to further control the bending displacement of the second main wall 44 near the first periphery 31, and to further reduce the dimension of the gap between the inside surface of the second main wall 44 and each aluminum electrolytic capacitor 30. Moreover, each corner is a part that has no effect on mounting of each component or the distribution of wiring patterns on the circuit board, and consequently the extent to which the circuit board receivers 57-60 that are a first reinforcement and the circuit board anchor ribs 61-64 that are a second reinforcement limit circuit formation area on the circuit board is extremely low.

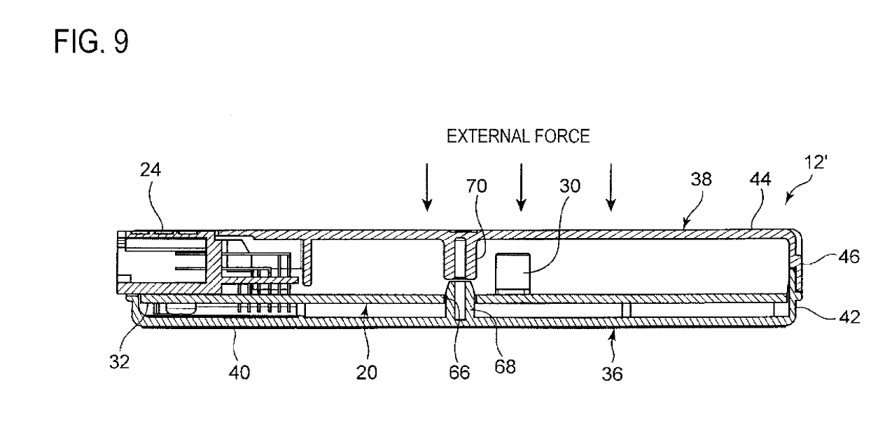

This result is further clarified through a comparison with the comparison example shown in FIG. 9, for example. In this comparison example, a penetrating hole 66 is provided substantially in the center of the circuit board 20, a first reinforcing pillar 68 protrudes to the inside (upward in the drawing) from the first main wall 40 of the case body 36 and penetrates this penetrating hole 66, and a second reinforcing pillar 70 protrudes to the inside (downward in the drawing) from the second outer perimeter wall 46 of the cover 38 and abuts the first reinforcing pillar 68.

In the structure according to this comparison example, the two reinforcing pillars 68 and 70 mutually abut in the height direction of the unit case at the center of the case body 36 and the cover 38, and this configuration is effective at controlling bending displacement of the second main wall 44. However, with this structure, the penetrating hole 66 provided in the center of the circuit board 20 imposes considerable restrictions on the formation of electronic control circuits in the circuit board 20, and accordingly there are concerns that this structure could cause considerable enlargement of the required surface area of the circuit board 20. Furthermore, there are concerns that electric current flowing in a ring around the penetrating hole 66 could function as an antenna, and there are concerns that this could impose a considerable negative effect on the noise properties of this electronic control circuit.

In contrast, with this unit case 22, the plurality of aluminum electrolytic capacitors 30 are arranged along a specific periphery 31 and reinforcing is done at corners interposing this periphery 31, and thus there is substantially no effect on the electronic control circuits formed on the circuit board.

The positions where the first reinforcement and the second reinforcement are provided are not limited to positions corresponding to the respective corners of the circuit board 20 as described above. By providing the first and second reinforcements for at least a portion of a specific periphery (the periphery where the aluminum electrolytic capacitors 30 are arranged; the first periphery 31 in the above-described preferred embodiment) of the circuit board 20, effective reinforcement can be realized for reducing the height dimension of the unit case while effectively protecting the aluminum electrolytic capacitors. For example, the first and second reinforcements can have a shape extending in a direction along the first periphery 31 and interposing roughly the entire area thereof.

In addition, the number of aluminum electrolytic capacitors and the specific arrangement position thereof are not limited. For example, a plurality of aluminum electrolytic capacitors can be positioned respectively dispersed along two peripheries interposing any of the corners.

The specific shapes of the circuit board and unit case are not limited. These shapes may be, for example, trapezoidal or L-shaped. In addition, the unit case can have an outer perimeter wall in a shape corresponding to the shape of the circuit board without having the above-described interior wall 54.

Furthermore, the electronic control unit is not limited to being mounted in the case 14 of an electric connection box as shown in FIG. 1, and in addition, when mounted in the case, other mounting postures and other conditions are not limited. For example, the present invention can be effectively applied to various onboard electronic control units in which there is a possibility of the unit case receiving an external force in the height direction thereof.

What is claimed is:

1. An onboard electric connection box, comprising:
an electronic control unit that includes an electronic control circuit, a plurality of aluminum electrolytic capacitors, and a circuit board, the circuit board defining a first surface and a second opposite surface, and on which the electronic control circuit is formed; and
a unit case housing the circuit board, the unit case defining a first main wall facing the first surface in a housed state of the circuit board, a second main wall facing the second surface, and a perimeter wall encompassing the circuit board from an exterior and linking the first main wall and the second main wall;
wherein the capacitors are mounted on the second surface of the circuit board so as to extend along a specific periphery of the circuit board and be mutually connected in parallel, and the unit case has a height dimension capable of housing the aluminum electrolytic capacitors without the aluminum electrolytic capacitors contacting the inside surface of the second main wall.

2. The onboard electric connection box according to claim 1, wherein:
the unit case includes: (i) a first case member having a first side wall that defines the first main wall and a portion of the perimeter wall and into which the circuit board is insertable in an attitude with the first main wall and the first surface of the circuit board facing each other inside of the first side wall, and (ii) a second case member having a second side wall that defines the perimeter wall along with the second main wall and the first side wall, and being joined to the first case member so as to cover the circuit board in an attitude in which the second main wall faces the second surface of the circuit board;
the first case member has a first reinforcement protruding to an interior from the first side wall and linking to the first main wall, and the second case member has a second reinforcement protruding to the interior from the second side wall and linking to the second main wall; and
the positions of the first and second reinforcements are set so that, with the first case member and the second case member joined, the first and second reinforcements interpose in the height direction thereof both sides of a portion of at least the specific periphery of the circuit board.

3. The onboard electric connection box according to claim 2, wherein the circuit board has a plurality of corners, and the first and second reinforcements are provided so as to interpose these corners.

4. An onboard electronic control unit for use with a unit case, the unit case defining first and second main walls and a perimeter wall, the electronic control unit comprising:
an electronic control circuit;
a plurality of aluminum electrolytic capacitors; and
a circuit board defining a first surface and a second opposite surface on which the electronic control circuit is formed,
wherein the first main wall faces the first surface in a housed state of the circuit board, the second main wall faces the second surface, and the perimeter wall encompasses the circuit board from an exterior and links the first main wall and the second main wall; and
wherein the capacitors are mounted on the second surface of the circuit board so as to extend along a specific periphery of the circuit board and be mutually connected in parallel, and the unit case has a height dimension capable of housing the aluminum electrolytic capacitors without the aluminum electrolytic capacitors contacting the inside surface of the second main wall.

5. The onboard electronic control unit according to claim 4, wherein:
the unit case includes: (i) a first case member having a first side wall that defines the first main wall and a portion of the perimeter wall and into which the circuit board is insertable in an attitude with the first main wall and the first surface of the circuit board facing each other inside of the first side wall, and (ii) a second case member having a second side wall that defines the perimeter wall along with the second main wall and the first side wall, and being joined to the first case member so as to cover the circuit board in an attitude in which the second main wall faces the second surface of the circuit board;
the first case member has a first reinforcement protruding to an interior from the first side wall and linking to the first main wall, and the second case member has a second reinforcement protruding to the interior from the second side wall and linking to the second main wall; and
the positions of the first and second reinforcements are set so that, with the first case member and the second case member joined, the first and second reinforcements interpose in the height direction thereof both sides of a portion of at least the specific periphery of the circuit board.

6. The onboard electronic control unit according to claim 5, wherein the circuit board has a plurality of corners, and the first and second reinforcements are provided so as to interpose these corners.
